(19) United States
(12) Patent Application Publication
(10) Pub. No.: US 2026/0191083 A1
(43) Pub. Date: Jul. 2, 2026

(54) SEMICONDUCTOR DEVICE PACKAGE AND METHOD OF MANUFACTURING THE SAME

(71) Applicant: OIP Technology Pte Ltd, Singapore (SG)

(72) Inventor: Mok Chuang Luen, Singapore (SG)

(21) Appl. No.: 19/438,113

(22) Filed: Dec. 31, 2025

(30) Foreign Application Priority Data
Dec. 31, 2024 (CN) 202411984154.9

(51) Int. Cl. H10W 74/10; H10W 70/06; H10W 70/09; H10W 70/40; H10W 72/00; H10W 74/01; H10W 90/00; H10W 90/10

(52) U.S. Cl. CPC H10W 74/121; H10W 70/06; H10W 70/09; H10W 70/417; H10W 72/01323; H10W 72/823; H10W 74/01; H10W 90/10; H10W 90/736

(57) ABSTRACT

The present invention provides a semiconductor device package and a method of manufacturing the package. The method manages to obtain a thick copper thickness exceeding 40 μm on both sides of each chip by forming copper pattern(s) and a wiring layer through printing or electroplating, overcoming the 40-μm copper thickness limitation associated with the conventional processes and promising better heat dissipation.

### CROSS-REFERENCES TO RELATED APPLICATION

This application claims the priority of Chinese patent application number 202411984154.9, filed on Dec. 31, 2024, the entire contents of which are incorporated herein by reference.

### TECHNICAL FIELD

The present invention relates to the field of semiconductor technology and, in particular, to a semiconductor device package and a method of manufacturing the package.

### BACKGROUND

In conventional semiconductor device packages, for any chip with pins on both sides, it is necessary to provide thick copper on both sides for heat dissipation. However, limited by the existing fabrication processes, copper can be formed to a thickness of only 40 μm or less in conventional packages. Moreover, conventional thick copper is alloyed and cannot provide good heat dissipation.

### SUMMARY

It is an object of the present invention to provide a semiconductor device package and a method of manufacturing it, which overcome the 40-μm thickness limitation associated with conventional heat-dissipating metals and promises better heat dissipation.

To this end, the present invention provides a method of manufacturing a semiconductor device package, which includes the steps of:
forming at least one spaced-apart copper pattern on a temporary carrier by printing or electroplating, each copper pattern including a conductive member and a first connecting member spaced apart from the conductive member;
attaching a chip to each first connecting member, each chip defining a front side and a backside, each chip provided with at least one pin on each of the front side and the backside, the front side oriented towards the first connecting member, all pins on the front side electrically connected to the first connecting member;
forming a first encapsulation layer, which fills a gap between the conductive member and the first connecting member and surrounds both the conductive member and the first connecting member, the conductive member and all pins on the backside of the chip being exposed out of the first encapsulation layer;
forming a wiring layer on a surface of the first plastic encapsulation layer proximal to the backside by printing or electroplating, the wiring layer electrically connected both to all pins on the backside of each chip and to the conductive member, thereby electrically connecting all pins on the backside of each chip to the front side via the conductive member;
forming a second encapsulation layer, which covers the wiring layer; and
removing the temporary carrier.

Optionally, the conductive member and the first connecting member may each have a thickness greater than 40 μm and the wiring layer may have a thickness greater than 40 μm.

Optionally, each conductive member may include at least one conductive post and each first connecting member may include at least one first solder pad, wherein attaching a chip to each first connecting member includes:
applying a silver paste to a surface of each first solder pad facing away from the temporary carrier by printing or dispensing, thereby forming a first silver paste layer; and
electrically connecting each first connecting member to a chip via the first silver paste layer.

Additionally, each chip may be provided with at least one first pin on the front side and at least one second pin on the backside, each first pin on the chip aligned with a respective one of the at least one first solder pad in the first connecting member and electrically connected to the respective one of the at least one first solder pad in the first connecting member via the first silver paste layer, and
wherein a silver paste is applied to each second pin by printing or dispensing, thereby forming a second silver paste layer.

Additionally, each conductive post may be inverted T-shaped and rectangular in shape.

Additionally, the number of first pins of each chip may be the same as the number of the first solder pads in the corresponding first connecting member, and the number of second pins of each chip may be the same as the number of the conductive posts in the corresponding first connecting member.

Additionally, a distance from a surface of the temporary carrier to a surface of each second silver paste layer away from the backside may be smaller than a height of the conductive post.

Optionally, forming the wiring layer may include:
forming the wiring layer on the first plastic encapsulation layer by printing of a silver or copper paste, or by electroplating of copper.

In another aspect of the present invention, there is provided a semiconductor device package including a first plastic encapsulation layer and a second plastic encapsulation layer, the first plastic encapsulation layer encapsulating therein at least one spaced-apart copper pattern and at least one chip, each copper pattern including a conductive member and a first connecting member spaced apart from the conductive member, each first connecting member attached thereto with a chip, each chip defining a front side and a backside and provided with at least one pin on each of the front side and the backside, the front side oriented towards the first connecting member, all pins on the front side electrically connected to the first connecting member, the first plastic encapsulation layer filling a gap between the conductive member and the first connecting member and surrounding both the conductive member and the first connecting member, the conductive member and all pins on the backside of the chip being exposed out of the first plastic encapsulation layer, the first plastic encapsulation layer formed on its surface proximal to the backside with a wiring layer, the wiring layer electrically connected both to all pins on the backside of each chip and to the conductive member, thereby electrically connecting all pins on the backside of each chip to the front side via the conductive member, the second plastic encapsulation layer covering the wiring layer,
wherein the at least one copper pattern and the wiring layer are each formed by printing or electroplating.

Optionally, the conductive member and the first connecting member may each have a thickness greater than 40 μm and the wiring layer may have a thickness greater than 40 μm.

Compared with the prior art, the present invention has the surprising benefits as follows:

It provides a semiconductor device package and a method of manufacturing the package. The method includes the steps of: forming at least one spaced-apart copper pattern on a temporary carrier by printing or electroplating, each copper pattern including a conductive member and a first connecting member spaced apart from the conductive member; attaching a chip to each first connecting member, each chip defining a front side and a backside and provided with at least one pin on each of the front side and the backside, the front side oriented towards a respective one of the first connecting member, each pin on the front side electrically connected to the respective first connecting member; forming a first encapsulation layer, which fills gap(s) between the conductive member and the first connecting member and surrounds both the conductive member and the first connecting member, with the conductive member and each pin on the backside of the chip being exposed out of the first encapsulation layer; forming a wiring layer on a surface of the first plastic encapsulation layer proximal to the backside by printing or electroplating, the wiring layer electrically connected both to each pin on the backside of each chip and to the conductive member, thereby electrically connecting each pin on the backside of each chip to the front side through the conductive member; forming a second encapsulation layer, which covers the wiring layer; and removing the temporary carrier. According to the present invention, since the copper pattern(s) and wiring layer are both formed by printing or electroplating, copper can be formed to a thickness exceeding 40 μm on both sides of each chip, overcoming the 40-μm copper thickness limitation associated with the conventional processes and promising better heat dissipation.

### BRIEF DESCRIPTION OF THE DRAWINGS

FIGS. 1 to 12 are schematic diagrams showing intermediate structures resulting from process steps in a method of manufacturing a semiconductor device package according to embodiments of the present invention.

### LIST OF REFERENCE NUMERALS

100 temporary carrier; 101 copper film; 210, 220 conductive post; 231, 232, 241, 242 first solder pad; 250 first silver paste layer; 261 first chip; 262 second chip; 270 second silver paste layer; 281, 282 connecting wire; 310 first encapsulation layer; 320 second encapsulation layer.

### DETAILED DESCRIPTION

Semiconductor device packages and methods according to the present invention will be described in greater detail below. The present invention will be described in greater detail below with reference to the accompanying drawings, which present preferred embodiments of the invention. It would be appreciated that those skilled in the art can make changes to the invention disclosed herein while still obtaining the beneficial results thereof. Therefore, the following description shall be construed as being intended to be widely known by those skilled in the art rather than as limiting the invention.

For the sake of clarity, not all features of an actual implementation are described in this specification. In the following, description and details of well-known functions and structures are omitted to avoid unnecessarily obscuring the invention. It should be appreciated that in the development of any such actual implementation, numerous implementation-specific decisions must be made to achieve specific goals of the developers, such as compliance with system-related and business-related constrains, which may vary from one implementation to another. Moreover, it should be appreciated that such a development effort might be complex and time consuming, but would nevertheless be a routine undertaking for those of ordinary skill in the art.

Objects and features of the present invention will become more apparent from the following description of specific embodiments of the present invention, which is made with reference to the appended drawings. Note that the figures are rather simplified and not necessarily drawn to exact scale, with the only intention to facilitate easy and clear description of the embodiments disclosed herein.

In an embodiment of the present invention, there is provided a method of manufacturing a semiconductor device package, which includes the steps of:
S1) forming at least one spaced-apart copper pattern on a temporary carrier by printing or electroplating, each copper pattern including a conductive member and a first connecting member spaced apart from the conductive member. The temporary carrier may be an etchable carrier, peelable carrier, thermal release carrier, or UV release carrier, and the copper pattern is built up using a two-step photolithography process to ensure precise patterning.
S2) attaching a chip to each first connecting member, each chip defining a front side and a backside and provided with at least one pin on each of the front side and the backside, the front side oriented towards a respective one of the first connecting member(s), each pin on the front side electrically connected to the respective first connecting member;
S3) forming a first encapsulation layer, which fills gap(s) between the conductive member(s) and the first connecting member(s) and surrounds both the conductive member(s) and the first connecting member(s), with the conductive member(s) and each pin on the backside of the chip being exposed out of the first encapsulation layer;
S4) forming a wiring layer on a surface of the first encapsulation layer proximal to the backside(s) by printing or electroplating, the wiring layer electrically connected both to each pin on the backside of each chip and to the conductive member(s), thereby electrically connecting each pin on the backside of each chip to the front side through the conductive member(s);
S5) forming a second encapsulation layer, which covers the wiring layer; and
S6) removing the temporary carrier.

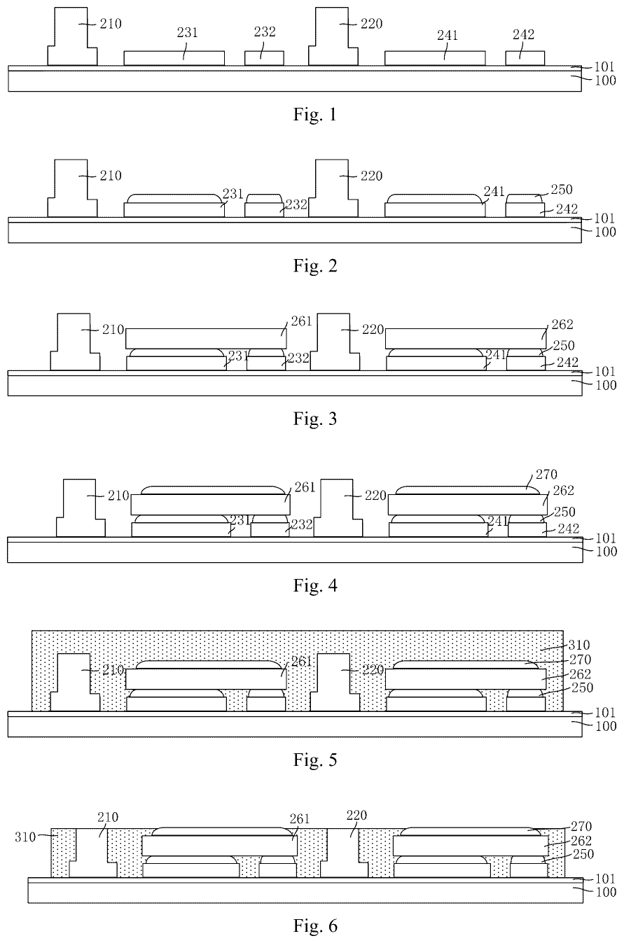

A method of manufacturing a semiconductor device package according to an embodiment of the present invention will be described in detail below with reference to FIGS. 1 to 12.

Referring to FIG. 1, first of all, in step S1, at least one spaced-apart copper pattern is formed on a temporary carrier 100 by printing or electroplating. Each copper pattern includes a conductive member and a first connecting member spaced apart from the conductive member.

In particular, this step may be as follows:

A temporary carrier 100 is provided, which may be, for example, rectangular or circular in shape. The temporary carrier 100 may be an iron carrier with a 3-5 μm thick copper coating on its surface.

Subsequently, at least one spaced-apart copper pattern is formed on the copper coating by printing or electroplating. Each copper pattern may be electrically connected to a chip. Each copper pattern includes a conductive member and a first connecting member spaced apart from the conductive member. The conductive member may include at least one conductive post, and the first connecting member may include at least one first solder pad. Each conductive post may be inverted T-shaped and rectangular in shape. Each conductive post and each first solder pad may be made of pure copper. In this way, the thick copper (consisting of the conductive post(s) and the first solder pad(s)) on one side of each chip can provide better heat dissipation than conventional copper alloys. The conductive member(s) and the first connecting member(s) may each have a thickness greater than 40 μm. As copper can be formed to a thickness exceeding 40 μm using a printing or electroplating technique, the present embodiment overcomes the 40-μm thickness limitation associated with conventional heat-dissipating metals.

As shown in FIGS. 2 to 4, in step S2, a chip is attached to each first connecting member. Each chip defines a front side and a backside and is provided with at least one pin on each of the front side and the backside. The front side is oriented towards the respective first connecting member, and each pin on the front side is electrically connected to the respective first connecting member.

In particular, this step may be as follows:

Referring to FIG. 2, a silver paste may be printed or dispensed on a surface of each first solder pad facing away from the temporary carrier, forming a first silver paste layer 250.

Referring to FIG. 3, a chip may be then attached and electrically connected to each first connecting member through the respective first silver paste layer 250. Each chip defines a front side and a backside, and the front side is oriented towards the respective first connecting member. Each chip is provided with at least one first pin on the front side and at least one second pin on the backside. Each first pin on each chip may be aligned with, and electrically connected by the respective first silver paste layer 250 to, a respective one of the first solder pad(s) in the respective first connecting member. There may be as many first pin(s) in each chip as there is/are first solder pad(s) in the respective first connecting member, and there may be as many second pin(s) in each chip as there is/are conductive post(s) in the respective first connecting member.

In the illustrated example, there are a first chip 261 and a second chip 262, each of which has two first pins and one second pin. Moreover, each copper pattern includes two conductive members and two first connecting members. One of the first connecting members has two first solder pads 231, 232, and one of the conductive members has one conductive post 210. The other first connecting member has two first solder pads 241, 242, and the other conductive member has one conductive post 220. The two first pins of the first chip 261 are connected to the respective first solder pads 231, 232, and the two first pins of the second chip 262 are connected to the respective first solder pads 241, 242.

Referring to FIG. 4, a silver paste may be then printed or dispensed on each second pin, forming a second silver paste layer 270.

The surface of the temporary carrier 100 may be spaced from a surface of each second silver paste layer 270 facing away from the backside at a distance smaller than a height of the conductive post(s). In this way, during the subsequent removal by grinding of the first encapsulation layer 310 that overlies the second pin(s), the conductive post(s) may be exposed first, avoiding excessive loss of the second silver paste layer(s) 270 that may arise from overgrinding due to an insufficient height of the conductive post(s).

As shown in FIGS. 5 to 7, in step S3, a first encapsulation layer 310 is formed, which fills gap(s) between the conductive member(s) and the first connecting member(s) and surrounds the conductive member(s) and the first connecting member(s), with the conductive member(s) and each pin on the backside of each chip being exposed out of the first encapsulation layer 310.

In particular, this step may be as follows:

Referring to FIG. 5, an encapsulation material may be applied so as to fill gap(s) between the conductive member(s) and the first connecting member(s) and surround the conductive member(s) and the first connecting member(s), and then solidified to form a first encapsulation layer 310 having a thickness greater than the height of the conductive post(s). Thus, the first encapsulation layer 310 can cover the conductive post(s) and the second silver paste layer(s) 270 from the backside.

Examples of the material of the first encapsulation layer 310 may include epoxy resins containing 85-90% of silica particles and a polymer material.

Next, in one example, referring to FIG. 6, the first encapsulation layer 310 may be thinned by grinding from the backside so that the conductive post(s) and the second silver paste layer(s) 270 are exposed.

Since the distance from the surface of the temporary carrier 100 to the surface of each second silver paste layer 270 facing away from the backside is smaller than the height of the conductive post(s), the conductive post(s) may be partially ground away in this step, making a height of the ground conductive post(s) becomes equal to the distance from the surface of the temporary carrier 100 to the surface of each second silver paste layer 270 facing away from the backside.

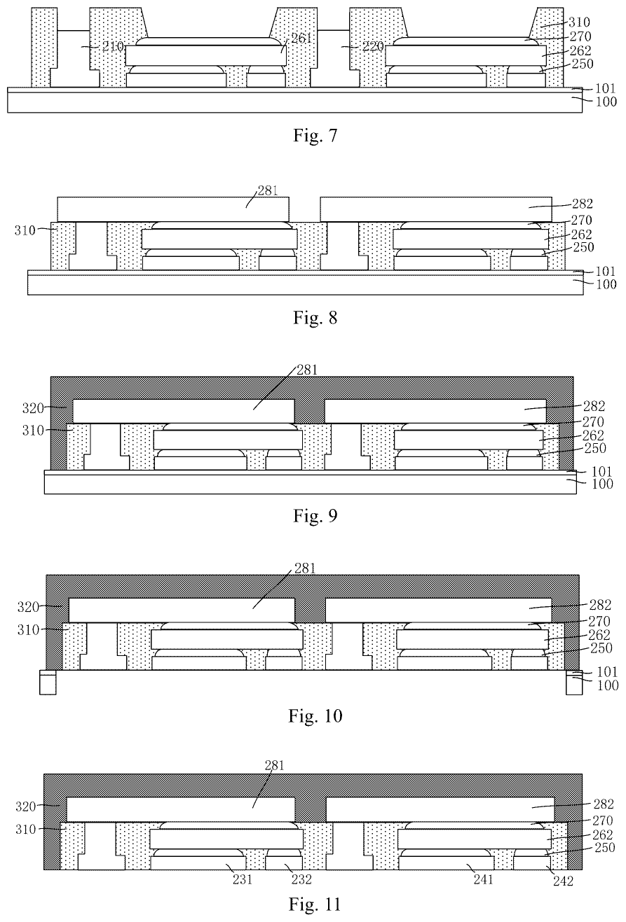

In another example, referring to FIG. 7, laser light may be used to remove, from the backside, the first encapsulation layer 310 overlying the second pin(s) and the conductive post(s), exposing the conductive post(s) and the second silver paste layer(s) 270.

As shown in FIG. 8, in step S4, a wiring layer is formed on a surface of the first encapsulation layer 310 proximal to the backside by printing or electroplating so as to be electrically connected to each pin on the backside of each chip and to the conductive member(s). Thus, each pin on the backside of each chip is electrically connected to the front side via the conductive member(s).

In particular, in this step, referring to FIG. 8, a wiring layer may be formed on a surface of the first encapsulation layer 310 proximal to the backside by printing of a silver or copper paste or by electroplating of copper. The wiring layer has a thickness greater than 40 μm.

The wiring layer may include at least one second connecting member each connected both to a respective one of the chip(s) and to a respective one of the first connecting member(s). Each second connecting member may include at least one connecting wire each connected both to a respective one of the second pin(s) in the respective chip and a respective one of the conductive post(s) in the respective first connecting member. Each connecting wire may have a thickness greater than 40 μm, for example, 100 μm, 200 μm or the like. Each connecting wire may be made of silver or copper. In this way, the thick copper (consisting of the connecting wire(s)) on one side of each chip can provide better heat dissipation than conventional copper alloys. Further, as copper can be formed to a thickness exceeding 40 μm using a printing or electroplating technique, the present embodiment overcomes the 40-μm copper thickness limitation associated with the conventional processes.

In the illustrated example, each second connecting member includes two connecting wire 281, 282. The connecting wire 281 is connected to both a second pin in the first chip 261 and the conductive post 210, and the connecting wire 282 is connected to both a second pin in the second chip 262 and the conductive post 220.

As shown in FIG. 9, in step S5, a second encapsulation layer 320 is formed, which covers the wiring layer(s).

In particular, in this step, an encapsulation material may be applied onto the first encapsulation layer 310 and the wiring layer and solidified to form a second encapsulation layer 320. Examples of the material of the second encapsulation layer 320 may include epoxy resins containing 85-90% of silica particles and a polymer material.

As shown in FIGS. 10 to 12, in step S6, the temporary carrier 100 is removed by etching, peeling, thermal detach, or UV detach, followed by flash etching to remove seed copper.

In particular, this step may be as follows:

Referring to FIG. 10, in one example, a selective etching process may be carried out from the front side to etch the temporary carrier 100 to expose on the front side the first encapsulation layer 310, the conductive post(s) and the first solder pad(s), as well as part of the second encapsulation layer 320.

Referring to FIG. 11, in another example, an etching process may be performed to strip away the temporary carrier 100, exposing on the front side the first encapsulation layer 310, the second encapsulation layer 320, the conductive post(s) and the first solder pad(s).

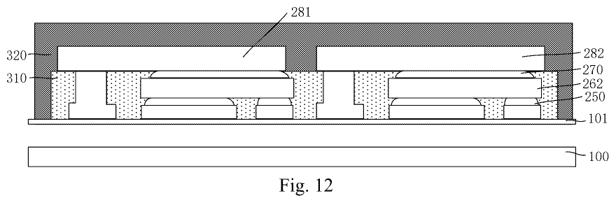

Referring to FIG. 12, in yet another example, at first, a lift-off process may be performed to remove the iron carrier, with the copper film 101 being retained. The copper film 101 may be then removed by flash etching (also known as quick etching), exposing on the front side the first encapsulation layer 310, the second encapsulation layer 320, the conductive post(s) and the first solder pad(s).

Finally, the semiconductor device package may be singulated from a large panel (e.g., 300×300 mm or larger) using a dicing process.

Referring to FIGS. 1 to 12, in embodiments of the present invention, there is also provided a semiconductor device package including a first encapsulation layer 310 and a second encapsulation layer 320. At least one spaced-apart copper pattern and at least one chip are encapsulated in the first encapsulation layer 310. Each copper pattern includes a conductive member and a first connecting member spaced apart from the conductive member. A chip is attached to each first connecting member. Each chip defines a front side and a backside and is provide with at least one pin on each of the front side and the backside. The front side is oriented towards the respective first connecting member, and each pin on the front side is electrically connected to the respective first connecting member. The first encapsulation layer 310 fills gap(s) between the conductive member(s) and the first connecting member(s) and surrounds the conductive member(s) and the first connecting member(s). The conductive member(s) and each pin on the backside of each chip are exposed out of the first encapsulation layer 310. A wiring layer is formed on a surface of the first encapsulation layer 310 proximal to the backside so as to be electrically connected both to each pin on the backside of each chip and to the conductive member(s). Thus, each pin on the backside of each chip is electrically connected to the front side via the conductive member(s). The second encapsulation layer 320 covers the wiring layer.

The wiring layer has a thickness greater than 40 μm. Moreover, the conductive member(s) and first connecting member(s) each have a thickness greater than 40 μm.

In summary, the present invention provides a semiconductor device package and a method of manufacturing the package. The method includes the steps of: forming at least one spaced-apart copper pattern on a temporary carrier by printing or electroplating, each copper pattern including a conductive member and a first connecting member spaced apart from the conductive member; attaching a chip to each first connecting member, each chip defining a front side and a backside and provided with at least one pin on each of the front side and the backside, the front side oriented towards a respective one of the first connecting member(s), each pin on the front side electrically connected to the respective first connecting member; forming a first encapsulation layer, which fills gap(s) between the conductive member(s) and the first connecting member(s) and surrounds both the conductive member(s) and the first connecting member(s), with the conductive member(s) and each pin on the backside of the chip being exposed out of the first encapsulation layer; forming a wiring layer on a surface of the first encapsulation layer proximal to the backside by printing or electroplating, the wiring layer electrically connected both to each pin on the backside of each chip and to the conductive member(s), thereby electrically connecting each pin on the backside of each chip to the front side through the conductive member(s); forming a second encapsulation layer which covers the wiring layer; and removing the temporary carrier. According to the present invention, since the copper pattern(s) and wiring layer are both formed by printing or electroplating, copper can be formed to a thickness exceeding 40 μm on both sides of each chip, overcoming the 40-μm copper thickness limitation associated with the conventional processes and promising better heat dissipation.

Further, it should be understood that, as used herein, the terms “first”, “second” and the like are only meant to distinguish various components, elements, steps, etc. from each other and are not intended to indicate logical or sequential orderings thereof, unless otherwise indicated or specified.

It would be appreciated that while the invention has been described above with reference to preferred embodiments thereof, it is not limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent alternatives and modifications made to the foregoing embodiments based on the substantive disclosure of the invention without departing from the scope thereof fall within the scope.

What is claimed is:

1. A method of manufacturing a semiconductor device package, comprising the steps of:
forming at least one spaced-apart copper pattern on a temporary carrier by printing or electroplating, each copper pattern comprising a conductive member and a first connecting member spaced apart from the conductive member;
attaching a chip to each first connecting member, each chip defining a front side and a backside, each chip provided with at least one pin on each of the front side and the backside, the front side oriented towards the first connecting member, all pins on the front side electrically connected to the first connecting member;
forming a first encapsulation layer, which fills a gap between the conductive member and the first connecting member and surrounds both the conductive member and the first connecting member, the conductive member and all pins on the backside of the chip being exposed out of the first encapsulation layer;
forming a wiring layer on a surface of the first plastic encapsulation layer proximal to the backside by printing or electroplating, the wiring layer electrically connected both to all pins on the backside of each chip and to the conductive member, thereby electrically connecting all pins on the backside of each chip to the front side via the conductive member;
forming a second encapsulation layer, which covers the wiring layer; and
removing the temporary carrier.

2. The method of claim 1, wherein the conductive member and the first connecting member each have a thickness greater than 40 μm and the wiring layer has a thickness greater than 40 μm.

3. The method of claim 1, wherein each conductive member comprises at least one conductive post and each first connecting member comprises at least one first solder pad, and wherein attaching a chip to each first connecting member comprises:
applying a silver paste to a surface of each first solder pad facing away from the temporary carrier by printing or dispensing, thereby forming a first silver paste layer; and
electrically connecting each first connecting member to a chip via the first silver paste layer.

4. The method of claim 3, wherein each chip is provided with at least one first pin on the front side and at least one second pin on the backside, each first pin on the chip aligned with a respective one of the at least one first solder pad in the first connecting member and electrically connected to the respective one of the at least one first solder pad in the first connecting member via the first silver paste layer, and
wherein a silver paste is applied to each second pin by printing or dispensing, thereby forming a second silver paste layer.

5. The method of claim 4, wherein each conductive post is inverted T-shaped and rectangular in shape.

6. The method of claim 4, wherein the number of first pins of each chip is the same as the number of the first solder pads in the corresponding first connecting member, and the number of second pins of each chip is the same as the number of the conductive posts in the corresponding first connecting member.

7. The method of claim 4, wherein a distance from a surface of the temporary carrier to a surface of each second silver paste layer away from the backside is smaller than a height of the conductive post.

8. The method of claim 1, wherein forming the wiring layer comprises:
forming the wiring layer on the first plastic encapsulation layer by printing of a silver or copper paste, or by electroplating of copper.

9. A semiconductor device package, comprising a first plastic encapsulation layer and a second plastic encapsulation layer, the first plastic encapsulation layer encapsulating therein at least one spaced-apart copper pattern and at least one chip, each copper pattern comprising a conductive member and a first connecting member spaced apart from the conductive member, each first connecting member attached thereto with a chip, each chip defining a front side and a backside and provided with at least one pin on each of the front side and the backside, the front side oriented towards the first connecting member, all pins on the front side electrically connected to the first connecting member, the first plastic encapsulation layer filling a gap between the conductive member and the first connecting member and surrounding both the conductive member and the first connecting member, the conductive member and all pins on the backside of the chip being exposed out of the first plastic encapsulation layer, the first plastic encapsulation layer formed on its surface proximal to the backside with a wiring layer, the wiring layer electrically connected both to all pins on the backside of each chip and to the conductive member, thereby electrically connecting all pins on the backside of each chip to the front side via the conductive member, the second plastic encapsulation layer covering the wiring layer,
wherein the at least one copper pattern and the wiring layer are each formed by printing or electroplating.

10. The semiconductor device package of claim 9, wherein the conductive member and the first connecting member each have a thickness greater than 40 μm and the wiring layer has a thickness greater than 40 μm.
